(19) United States
(12) Patent Application Publication
(10) Pub. No.: US 2017/0176497 A1
(43) Pub. Date: Jun. 22, 2017

(54) MICROELECTROMECHANICAL PROBE, METHOD OF MANUFACTURING THE SAME AND PROBE SET

(71) Applicant: MPI CORPORATION, CHU-PEI CITY (TW)

(72) Inventors: Shao-Lun WEI, CHU-PEI CITY (TW); Yu-Chen HSU, CHU-PEI CITY (TW); Mao-Fa SHEN, CHU-PEI CITY (TW); Chih-Hao HSU, CHU-PEI CITY (TW)

(21) Appl. No.: 15/379,887

(22) Filed: Dec. 15, 2016

(30) Foreign Application Priority Data
Dec. 16, 2015 (TW) 104142312

(51) Int. Cl. G01R 1/073; B81C 1/00; B81B 1/00

(52) U.S. Cl. CPC G01R 1/07357; B81B 1/008; B81C 1/00007

(57) ABSTRACT

A microelectromechanical probe is manufactured by a MEMS manufacturing process forming a probe body and a cutting process providing a pinpoint portion a cutting face. The probe has a top surface, a body portion, and a pinpoint portion extended in a probing direction from the body portion and provided with first and second sides and a probing end oriented in the probing direction. The cutting face is provided on the top surface, adjoins the first and second sides and the probing end, and has at least one cut mark formed by the cutting process, extended from the first side to the second side and non-parallel to the probing direction. The cutting face descends from an edge cut mark to the probing end.

### BACKGROUND OF THE INVENTION

1. Field of the Invention

The present invention relates generally to a probe used in a probe card for probing a device under test (hereinafter referred to as “DUT”), and more particularly to a microelectromechanical probe, a method of manufacturing the microelectromechanical probe, and a probe set using the microelectromechanical probe.

2. Description of the Related Art

FIG. 1 shows a conventional buckling probe 10, namely cobra probe, which is manufactured by a microelectromechanical system manufacturing process (hereinafter referred to as “MEMS manufacturing process”). In the manufacturing process, the buckling probe 10 is formed on a substrate (not shown) with a lying posture on the substrate. Specifically speaking, before the buckling probe 10 is completely formed, a photoresist layer is formed on the substrate and then defined by a photomask and developed with a hollow pattern by photolithography technique in a way that the hollow pattern of the photoresist layer has a shape corresponding to the shape of front and rear surfaces 11, 12 of the probe 10. Thereafter, the probe 10 is formed in the hollow pattern of the photoresist layer by electroplating. When being completely formed, the probe 10 lies on the substrate in a way that the front and rear surfaces 11, 12 of the probe 10 are parallel to the substrate.

Compared with the traditional machining process, the aforesaid MEMS manufacturing process is faster, more favorable for batch and mass production and more precise in manufacturing the probe 10. However, the MEMS manufacturing process causes a restriction on the shape of the probe 10. That is, the pinpoint portion 13 of the probe 10 can taper off by only left and right sides 131, 132 thereof inclining to approach each other, but front and rear sides 133, 134 of the pinpoint portion 13 are hard to be made inclining to approach each other. Therefore, the pinpoint portion 13 has an elongated probing end 135 with a certain surface area for contacting the DUT. The probing end 135 is simply depicted as a straight line in FIG. 1. Actually, the probing end 135 is shaped as an elongated arc surface with a certain width. Such probing end 135 has disadvantages of making relatively larger probe marks on the DUT and having less recognizable image in the automatic pinpoint recognition process. Besides, the probing end 135 may be not sharp enough to pierce the passivation layer on the surface of the DUT, causing undesired faults or errors in testing the DUT. If the probe 10 is applied with a relatively larger force to make sure that the probing end 135 can always pierce through the passivation layer to probe the DUT, this approach will cause heavy wear to the probe 10 and shorten the service life of the probe 10.

### SUMMARY OF THE INVENTION

The present invention has been accomplished in view of the above-noted circumstances. It is an objective of the present invention to provide a microelectromechanical probe, the probing end of the pinpoint portion of which has relatively smaller area, thereby making relatively smaller probe marks upon probing the DUT, easily piercing the passivation layer of the DUT, and more recognizable in the automatic pinpoint recognition process.

To attain the above objective, the present invention provides a microelectromechanical probe which has a top surface, a body portion, and a pinpoint portion substantially extended in a probing direction from the body portion and provided with a first side, a second side opposite to the first side and a probing end substantially oriented in the probing direction. The microelectromechanical probe is adapted to move relative to a DUT in the probing direction to contact the DUT by the probing end. The pinpoint portion has a cutting face provided on the top surface, adjoining the first side, the second side and the probing end, and having at least one cut mark formed by a cutting process. The at least one cut mark is substantially extended from the first side to the second side and non-parallel to the probing direction, and comprises an edge cut mark located at an edge of the cutting face. The cutting face descends from the edge cut mark to the probing end.

In other words, the microelectromechanical probe of the present invention is initially formed by a MEMS manufacturing process, and then a cutting process is performed to remove a part of the initially formed pinpoint portion so as to simultaneously form the cutting face and cut off a part of the initially formed probing end. As a result, the probing end of the microelectromechanical probe of the present invention has relatively smaller area, thereby making relatively smaller probe marks upon probing the DUT, easily piercing the passivation layer of the DUT, and more recognizable in the automatic pinpoint recognition process. Besides, the at least one cut mark is formed in a way that the cutting process is performed to cut the pinpoint portion from the first side to the second side in a cutting direction non-parallel to the probing direction. In this way, a plurality of probes can be cut in a same cutting process, so that the microelectromechanical probe of the present invention is favorable for batch and mass production.

It is another objective of the present invention to provide a method of manufacturing the aforesaid microelectromechanical probe.

To attain the above objective, the present invention provides a method of manufacturing a microelectromechanical probe, which includes the steps of:

a) forming a probe body on a substrate by a microelectromechanical system manufacturing process in a way that the probe body has a bottom surface facing the substrate, a top surface opposite to the bottom surface, a body portion, and a pinpoint portion which is substantially extended in a probing direction from the body portion and provided with a first side, a second side opposite to the first side and a probing end substantially oriented in the probing direction; and

b) cutting the pinpoint portion of the probe body from the first side to the second side in a cutting direction non-parallel to the probing direction by a cutting tool, so as to simultaneously provide the pinpoint portion a cutting face on the top surface and reduce an area of the probing end in a way that the cutting face is provided at an edge thereof with an edge cut mark and the cutting face descends from the edge cut mark to the probing end.

Preferably, in the MEMS manufacturing process in the step a) of the aforesaid method, a plurality of probe bodies are formed on the substrate in a way that the probe bodies are substantially arranged at a same posture and the probing ends of the probe bodies are aligned in the cutting direction; in the step b), the probe bodies, which are aligned in an imaginary straight line in the cutting direction, are cut by the cutting tool in a same cutting process. In this way, a plurality of probes can be cut in the same cutting process, so that the method is favorable for batch and mass production of the microelectromechanical probe.

Preferably, in the step a) of the aforesaid method, a sacrificial layer is formed on the substrate in the MEMS manufacturing process, and the probe body is fixed on the substrate by the sacrificial layer. The sacrificial layer is removed after the step b), so that the probe body is separated from the substrate. In this way, the probe body is stably fixed on the substrate by the sacrificial layer while the step b) is performed, such that potential problems of displacement and deformation of the probe body can be prevented in the cutting process. Such effect is remarkable particularly in the aforesaid cutting process for batch and mass production of the microelectromechanical probe.

Preferably, in the aforesaid method, the cutting direction is inclined relative to the probing direction at an angle. This means the at least one cut mark is inclined relative to the probing direction at the angle. As a result, in the image recognition process, when light is emitted to the pinpoint portion in a direction parallel to the probing direction and reflected by the cut mark of the cutting face, the associated reflected light will not be parallel to the probing direction. In other words, the aforesaid inclined cut mark makes the reflected light non-parallel to the incident light, thereby so effective in light extinction as to improve the image recognition in the automatic pinpoint recognition process. More preferably, the angle is larger than or equal to 45 degrees and smaller than or equal to 75 degrees so as to obtain desired effect of light extinction. However, the microelectromechanical probe of the present invention and the method of manufacturing the probe are unlimited to have the aforesaid feature. The cutting direction may be substantially perpendicular to the probing direction. This means, the at least one cut mark may be substantially perpendicular to the probing direction.

Preferably, the cutting face may be substantially shaped as one of a plane, a curved surface and a combination of multiple curved surfaces, wherein the single curved surface is optimal. For example, the cutting tool may be a ball nose milling cutter, an abrasive wheel or a form grinding wheel, for shaping the cutting face as the single curved surface by one-time processing or shaping the cutting face as the combination of multiple curved surfaces by multi-time processing. The cutting tool may be a special single-tooth or multi-tooth milling cutter, an abrasive wheel with single tapered side, or a ball nose milling cutter with relatively larger radius of curvature, for substantially shaping the cutting face as a plane.

The microelectromechanical probe of the present invention may, but unlimited to, be a straight or buckling vertical probe or a cantilever probe (also called N-shaped probe), which is formed and cut at a posture of lying horizontally. Besides, the cutting face is defined with a minimum length, which is a minimum distance measured in a direction parallel to the probing direction between the edge cut mark and the probing end, and a descending height, which is a minimum distance measured in a direction perpendicular to the probing direction between the edge cut mark and the probing end; the cutting face is preferably configured in a way that the minimum length is larger than or equal to 1.5 times of the descending height. Furthermore, in the case that the cutting face is substantially shaped as a plane, the cutting face is preferably configured to be inclined relative to the probing direction at an angle smaller than 33 degrees.

The present invention also provides a probe set including two aforesaid microelectromechanical probes, wherein the pinpoint portion of each of the microelectromechanical probes has a rear side substantially opposite to the cutting face. The rear sides of the pinpoint portions of the two microelectromechanical probes face each other. Such arrangement can make the distance between the probing ends of two adjacent probes relatively smaller, so as to satisfy the fine pitch requirement of usage.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is a schematic perspective view of a conventional microelectromechanical probe;

FIG. 2 is a schematic perspective view of a microelectromechanical probe according to a first preferred embodiment of the present invention;

FIGS. 3-4 are schematic sectional views respectively showing the steps a) and b) of a method of manufacturing the microelectromechanical probe according to the first preferred embodiment of the present invention;

FIG. 5 is a schematic top view of a part of the microelectromechanical probe according to the first preferred embodiment of the present invention;

FIG. 6 is a schematic lateral view of a part of the microelectromechanical probe according to the first preferred embodiment of the present invention;

FIG. 7 is a schematic top view showing the step b) of the method of manufacturing the microelectromechanical probe according to the first preferred embodiment of the present invention;

FIG. 8 is a schematic lateral view of a part of a microelectromechanical probe according to a second preferred embodiment of the present invention;

FIG. 9 is a schematic sectional view showing the step b) of a method of manufacturing the microelectromechanical probe according to a third preferred embodiment of the present invention;

FIG. 10 is a schematic top view of a part of a microelectromechanical probe according to the third preferred embodiment of the present invention;

FIG. 11 is a schematic top view of a part of a microelectromechanical probe according to a fourth preferred embodiment of the present invention;

FIG. 12 is a schematic top view showing the step b) of a method of manufacturing the microelectromechanical probe according to the fourth preferred embodiment of the present invention;

FIG. 13 is a schematic top view of a part of a microelectromechanical probe according to a fifth preferred embodiment of the present invention;

FIG. 14 is a schematic lateral view of a part of a microelectromechanical probe according to a sixth preferred embodiment of the present invention;

FIGS. 15-16 are schematic sectional views showing the step b) of a method of manufacturing the microelectromechanical probe according to the sixth preferred embodiment of the present invention;

FIG. 17 is a schematic perspective view of a microelectromechanical probe according to a seventh preferred embodiment of the present invention;

FIG. 18 is a schematic perspective view of a microelectromechanical probe according to an eighth preferred embodiment of the present invention; and

FIG. 19 is a schematic view of a probe set according to a ninth preferred embodiment of the present invention.

### DETAILED DESCRIPTION OF THE INVENTION

First of all, it is to be mentioned that same reference numerals used in the following preferred embodiments and the appendix drawings designate same or similar elements throughout the specification for the purpose of concise illustration of the present invention.

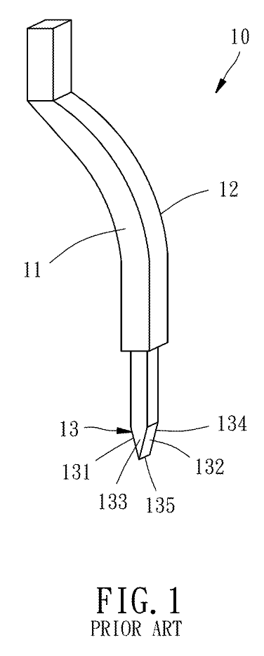

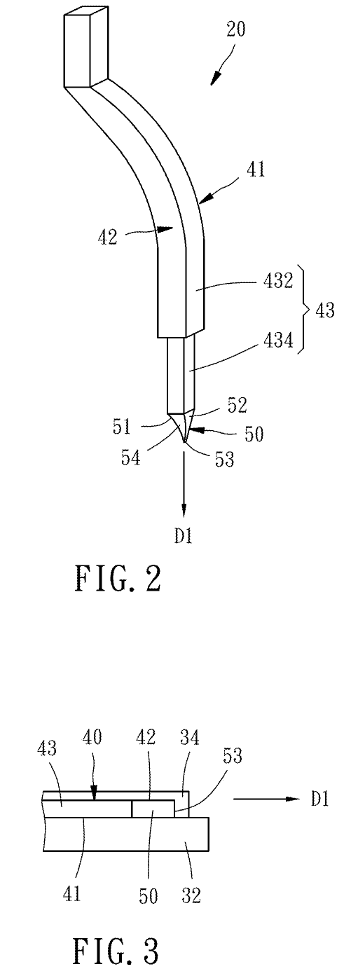

Referring to FIG. 2, a microelectromechanical probe 20 according to a first preferred embodiment of the present invention is similar to the conventional buckling probe 10 made by the MEMS manufacturing process as shown in FIG. 1, but has a difference in the configuration of the pinpoint portion therebetween. The method of manufacturing the microelectromechanical probe 20 will be described in the following paragraphs, and the structural features of the microelectromechanical probe 20 will be described at the same time. The method of manufacturing the microelectromechanical probe 20 includes the following steps.

a) As shown in FIG. 3, perform a MEMS manufacturing process to form a probe body 40 (like the probe 10 shown in FIG. 1) on a substrate 32 in a way that the probe body 40 has a bottom surface 41 (like the rear surface 12 of the probe 10) facing the substrate 32, a top surface 42 (like the front surface 11 of the probe 10) opposite to the bottom surface 41, a body portion 43, and a pinpoint portion 50 (like the pinpoint portion 13 of the probe 10) which is substantially extended in a probing direction D1 from the body portion 43 and provided with, as shown in FIG. 5, a first side 51 (like the left side 131 of the pinpoint portion 13 of the probe 10), a second side 52 (like the right side 132 of the pinpoint portion 13 of the probe 10) opposite to the first side 51 and a probing end 53 substantially oriented in the probing direction D1.

The top surface 42 and the bottom surface 41 mentioned in the present invention are named correspondingly to the state the probe is manufactured, not the state the probe is in use. The term “probing direction” used in the present invention is defined as the direction along which the probe and the DUT (not shown) are relatively moved toward each other, such that the DUT is contacted by the probing end 53 when the microelectromechanical probe 20 is used to probe the DUT. Besides, the body portion 43 of the microelectromechanical probe 20 in this embodiment includes an upper section 432 with larger width and thickness, and a lower section 434 with smaller width and thickness. The pinpoint portion 50 is extended and declines in width thereof from the bottom end of the lower section 434. However, the body portion 43 is unlimited to such configuration.

The MEMS manufacturing process mentioned in the step a) includes the steps of forming a sacrificial layer 34 (made of metal or photoresist that can be easily removed, for example) on the substrate 32 by photolithography technique and using a material, such as but unlimited to cobalt alloy (such as palladium-cobalt alloy, nickel-cobalt alloy and so on) to form the probe body 40 in the sacrificial layer 34 by electroplating. These steps of the MEMS manufacturing process belong to conventional technology well known by person having ordinary skill in the art, and therefore need not to be detailedly specified hereunder.

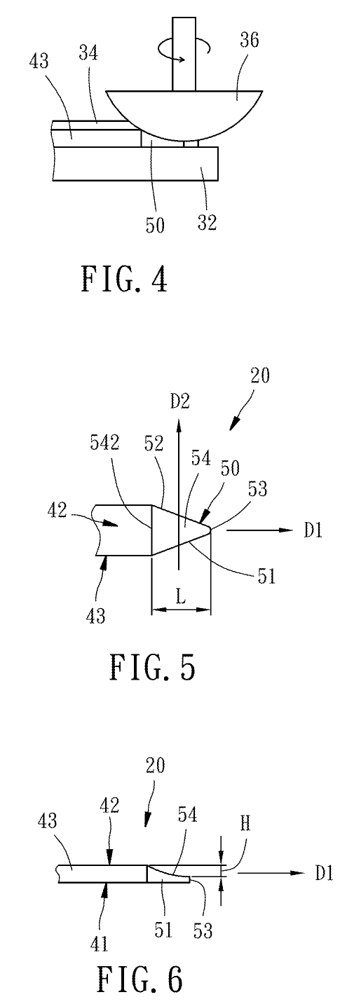

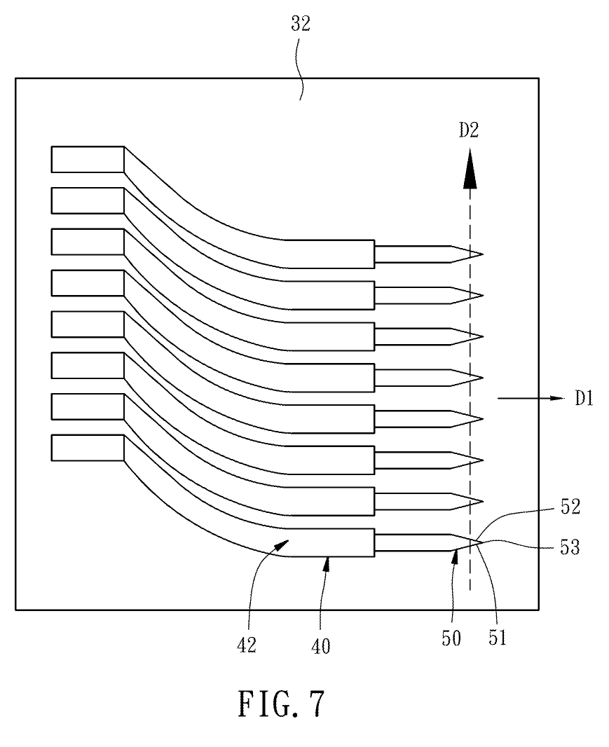

b) As shown in FIG. 4, perform a cutting process to cut the pinpoint portion 50 of the probe body 40 from the first side 51 to the second side 52 in a cutting direction D2 (as shown in FIGS. 5 and 7) non-parallel to the probing direction D1 by a cutting tool 36 such as a milling cutter, so as to simultaneously provide the pinpoint portion 50 a descending cutting face 54 (as shown in FIGS. 2 and 6) on the top surface 42 and reduce area of the probing end 53.

As a result, the cutting face 54 adjoins the first side 51, the second side 52 and the probing end 53, and has at least one cut mark 542 formed by the cutting process. The at least one cut mark 542 is substantially extended from the first side 51 to the second side 52. Because the at least one cut mark 542 is produced in the cutting direction D2, it is also non-parallel to the probing direction D1. In this embodiment, the cutting tool 36 is a ball nose milling cutter, the obvious cut mark produced by which only includes an edge cut mark 542 located at an edge of the cutting face 54. The cutting face 54 descends from the edge cut mark 542 to the probing end 53. Besides, the cutting direction D2 in this embodiment is substantially perpendicular to the probing direction D1, so the cut mark 542 is substantially perpendicular to the probing direction D1.

In other words, the microelectromechanical probe of the present invention is initially formed by the MEMS manufacturing process, and then the cutting process is performed to remove a part of the initially formed pinpoint portion 50 so as to simultaneously form the cutting face 54 and cut off a part of the initially formed probing end 53. Therefore, the probing end 53 of the microelectromechanical probe of the present invention has relatively smaller area, thereby making relatively smaller probe marks upon probing the DUT, easily piercing the passivation layer of the DUT, and more recognizable in the automatic pinpoint recognition process. The cutting process mentioned in the present invention refers to any machining process which uses a cutting tool to contact a work piece directly and remove a part of the work piece, including milling, grinding, abrasive cutting and so on.

Besides, the cutting process is performed to cut the pinpoint portion 50 from the first side 51 to the second side 52 in the cutting direction D2 non-parallel to the probing direction D1. Therefore, a plurality of probes can be cut in the aforesaid way in a same cutting process. This means, as shown in FIG. 7, a plurality of probe bodies 40 may be manufactured on the substrate 32 in the MEMS manufacturing process in the step a). The probe bodies 40 are substantially arranged at the same posture, and the probing ends 53 of the probe bodies 40 are aligned in the cutting direction D2. In the step b), the probe bodies 40, which are aligned in an imaginary straight line in the cutting direction D2, are cut by the cutting tool 36 in the same cutting process. Therefore, the present invention is favorable for batch and mass production of the microelectromechanical probe. For the simplification of the figure and the convenience of illustration, the sacrificial layer 34 and the cutting tool 36 are not shown in FIG. 7.

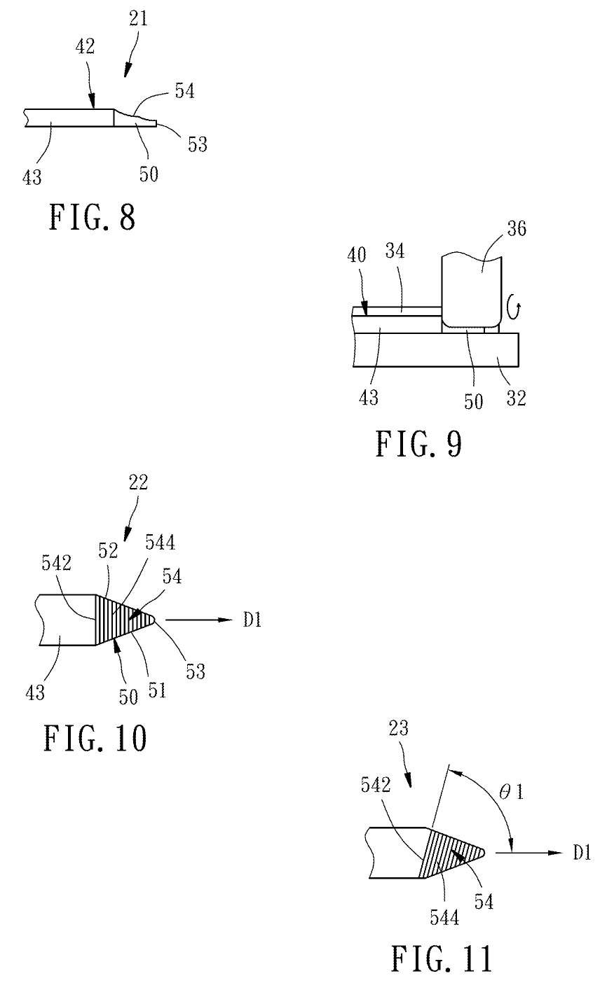

In the first preferred embodiment, the cutting face 54 is formed by one-time processing, thereby shaped as a curved surface. However, the cutting face 54 may be formed by multi-time processing to be shaped as a combination of multiple curved surfaces. Taking the microelectromechanical probe 21 according to a second preferred embodiment of the present invention as shown in FIG. 8 as an example, the cutting face 54 thereof is shaped as a combination of two curved surfaces.

As shown in FIGS. 3-4, in the process of the aforesaid method, the probe body 40 is fixed on the substrate 32 by the sacrificial layer 34 formed in the step a). The sacrificial layer 34 is removed after the step b) so that the probe body 40 is separated from the substrate 32. In this way, the probe body 40 can be stably fixed on the substrate 32 by the sacrificial layer 34 while the step b) is performed, such that problems of displacement and deformation of the probe body, which may occur in the cutting process, can be prevented. Such effect is remarkable particularly in the aforesaid cutting process for batch and mass production of the microelectromechanical probe. However, the present invention is unlimited to have the aforesaid feature. The sacrificial layer 34 may be removed after the step a). This means, while the step b) is performed, the probe body 40 is unlimited to be fixed by the sacrificial layer 34 and unlimited to be disposed on the substrate 32.

Referring to FIGS. 9-10, a microelectromechanical probe 22 according to a third preferred embodiment of the present invention is similar to the aforesaid probe 20 according to the first preferred embodiment. However, in the step b) of the method of manufacturing the microelectromechanical probe 22, the cutting tool 36 is an abrasive wheel as shown in FIG. 9, the cutting face 54 produced by which is also shaped as a curved surface, but has other cut marks 544 in addition to the edge cut mark 542. The cut marks 544 may be even provided all over the cutting face 54 regularly.

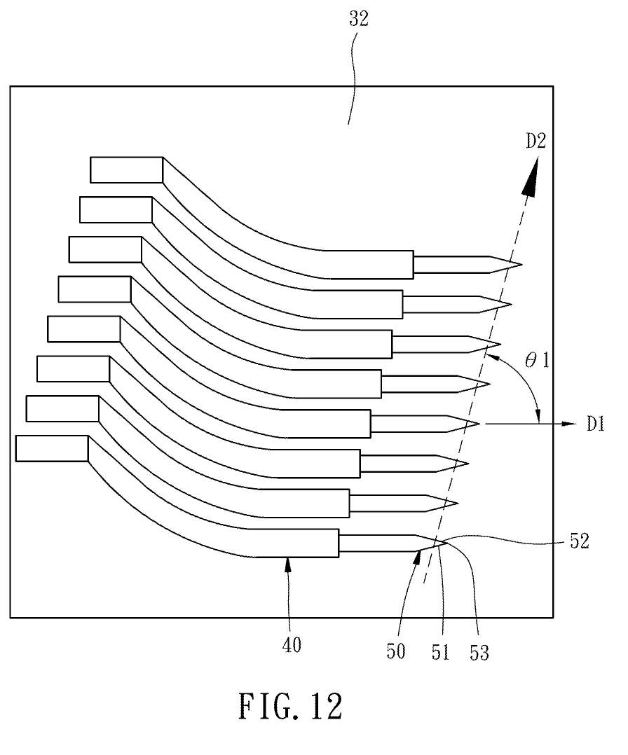

When the automatic pinpoint recognition process is performed subject to the microelectromechanical probe 22, light is emitted to the pinpoint portion 50 in a direction parallel to the probing direction D1. Because the cut marks 542, 544 perpendicular to the probing direction D1 are perpendicular to the light, the cut marks 542, 544 will reflect incident light back in a direction parallel to the incident light, which is liable to deteriorate the image distinguishable degree during the image recognition process. To solve this problem, a microelectromechanical probe 23 according to a fourth preferred embodiment of the present invention as shown in FIG. 11, and the cutting process for the probe 23 as shown in FIG. 12, are provided. In FIG. 12, the cutting direction D2 is inclined relative to the probing direction D1 at an angle θ1, which makes the cut marks 542, 544 of the cutting face 54 inclined relative to the probing direction D1 at the angle θ1, as shown in FIG. 11. In this way, in the automatic pinpoint recognition process, the aforesaid inclined cut marks will make the reflected light non-parallel to the incident light, thereby so effective in light extinction as to improve the image recognition. The angle θ1 is preferably larger than or equal to 45 degrees and smaller than or equal to 75 degrees for obtaining desired effect of light extinction. In this embodiment, the angle θ1 is 75 degrees. For the simplification of the figure and the convenience of illustration, the sacrificial layer 34 and the cutting tool 36 are not shown in FIG. 12.

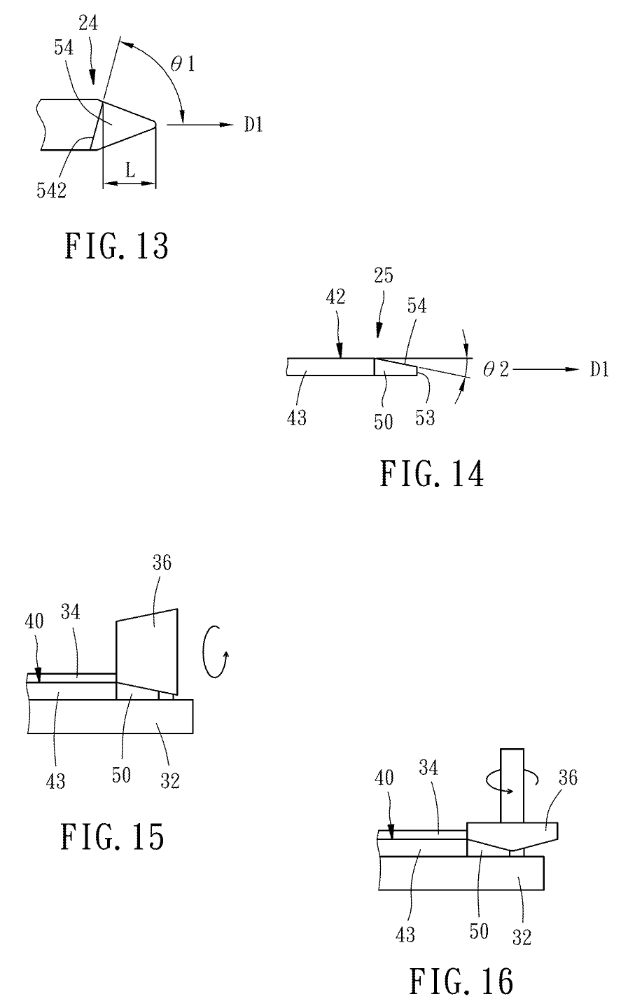

The aforesaid inclined cutting process for producing the inclined cut mark is unlimited to use the abrasive wheel as the cutting tool. Taking a microelectromechanical probe 24 according to a fifth preferred embodiment of the present invention as shown in FIG. 13 as an example, the cutting face 54 thereof is formed by a ball nose milling cutter in the inclined cutting process as shown in FIG. 12.

The cutting face 54 may be shaped as a plane, such as the cutting face 54 of the microelectromechanical probe 25 according to a sixth preferred embodiment of the present invention as shown in FIG. 14. This means, the cutting face 54 may be a slope extended from the aforesaid edge cut mark 542 to the probing end 53. Such cutting face 54 may, but unlimited to, be formed by an abrasive wheel with single tapered side as shown in FIG. 15, or a special single-tooth or multi-tooth milling cutter as shown in FIG. 16. Alternately, a ball nose milling cutter with relatively larger radius of curvature may be used to substantially shape the cutting face 54 as a plane.

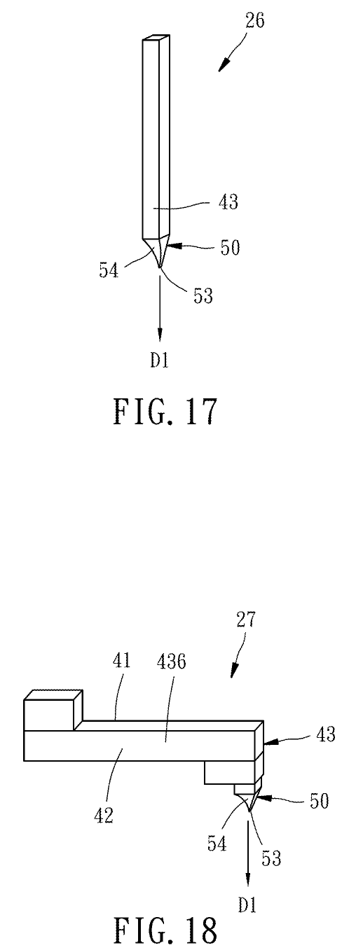

Referring to FIG. 17, a microelectromechanical probe 26 according to a seventh preferred embodiment of the present invention is similar to the aforesaid microelectromechanical probe 20 according to the first preferred embodiment. However, the body portion 43 of the microelectromechanical probe 26 in this embodiment has a straight shape, not a buckling shape. The technical features of each of the aforesaid embodiments can be applied to the straight vertical probe as provided in this embodiment.

Besides, the technical features of each of the aforesaid embodiments can be applied to the microelectromechanical probe 27 according to an eighth preferred embodiment of the present invention as shown in FIG. 18. The method of manufacturing the probe 27 is similar to the aforesaid method, but the probe body manufactured by the MEMS manufacturing process in the step a) is N-shaped. The probe body is similar in shape to the conventional cantilever probe (also called N-shaped probe), the body portion 43 of which has an elongated cantilever 436. After such cantilever probe is formed in the step a), and while it is cut in the step b), the N-shaped bottom surface 41 thereof is abutted on the aforesaid substrate 32. In the step b), the cutting face 54 is provided at the pinpoint portion 50 of the probe body by the cutting process. The cutting face 54 is provided on the N-shaped top surface 42 and descends to the probing end 53.

In each of the aforesaid embodiments, the cutting face 54 is preferably configured to satisfy the following inequality.

L≧1.5H

Wherein, L is the minimum length of the cutting face 54, i.e. the minimum distance measured in a direction parallel to the probing direction D1 between the edge cut mark 542 and the probing end 53. In the case as shown in FIG. 5 that the cut mark is perpendicular to the probing direction D1, the cutting face 54 has a constant length, which is the minimum length L. In the case as shown in FIG. 13 that the cut mark is inclined relative to the probing direction D1 at the angle θ1, the cutting face 54 has a linear variation in length, and the minimum length L is that indicated in FIG. 13. H is the descending height of the cutting face 54, i.e. the minimum distance measured in a direction perpendicular to the probing direction D1 between the edge cut mark 542 and the probing end 53, as shown in FIG. 6.

Besides, in the case as shown in FIG. 14 that the cutting face 54 is substantially shaped as a plane, the angle θ2, at which the cutting face 54 is inclined relative to the probing direction D1, is preferably smaller than 33 degrees.

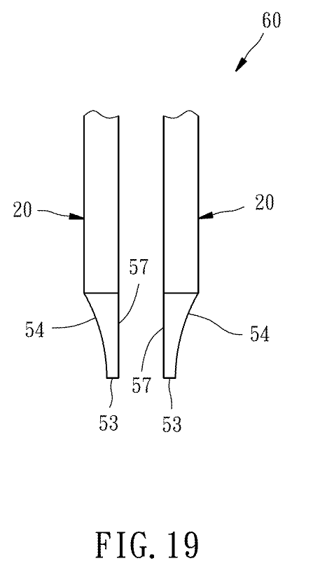

Referring to FIG. 19, the present invention also provides a probe set 60 including two microelectromechanical probes. In this embodiment, each of the microelectromechanical probes is configured as the aforesaid microelectromechanical probe 20 according to the first preferred embodiment. However, each of the microelectromechanical probes may be configured as the microelectromechanical probe according to any aforesaid embodiment. The pinpoint portion 50 of each of the microelectromechanical probes 20 has a rear side 57 substantially opposite to the cutting face 54. Taking the left probe 20 in FIG. 19 as an example, the cutting face 54 thereof substantially faces the left, and the rear side 57 thereof faces the right. In the probe set 60, the rear sides 57 of the pinpoint portions 50 of the two microelectromechanical probes 20 face each other. When the microelectromechanical probes of the present invention are used in the probe card according to the aforesaid arrangement to compose the probe set 60, the distance between the probing ends 53 of two adjacent probes is relatively smaller, so that the fine pitch requirement of usage can be satisfied. It should be mentioned that there are only two microelectromechanical probes 20 shown in FIG. 19, but the probe set 60 shown in the figure may include many microelectromechanical probes 20. The probe set 60 is unlimited to that in this embodiment including only two microelectromechanical probes 20.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A microelectromechanical probe comprising a top surface, a body portion, and a pinpoint portion which is substantially extended in a probing direction from the body portion and provided with a first side, a second side and a probing end substantially oriented in the probing direction, the microelectromechanical probe being adapted to move relative to a device under test in the probing direction to contact the device under test by the probing end;
wherein the pinpoint portion has a cutting face provided on the top surface, adjoining the first side, the second side and the probing end, and having at least one cut mark formed by a cutting process; the at least one cut mark is substantially extended from the first side to the second side and non-parallel to the probing direction, and comprises an edge cut mark located at an edge of the cutting face; the cutting face descends from the edge cut mark to the probing end.

2. The microelectromechanical probe as claimed in claim 1, wherein the cutting face is defined with a minimum length, which is a minimum distance measured in a direction parallel to the probing direction between the edge cut mark and the probing end, and a descending height, which is a minimum distance measured in a direction perpendicular to the probing direction between the edge cut mark and the probing end; the minimum length is larger than or equal to 1.5 times of the descending height.

3. The microelectromechanical probe as claimed in claim 1, wherein the cutting face is substantially shaped as a plane inclined relative to the probing direction at an angle smaller than 33 degrees.

4. The microelectromechanical probe as claimed in claim 1, wherein the cutting face is substantially shaped as one of a plane, a curved surface and a combination of multiple curved surfaces.

5. The microelectromechanical probe as claimed in claim 1, wherein the at least one cut mark is substantially perpendicular to the probing direction.

6. The microelectromechanical probe as claimed in claim 1, wherein the at least one cut mark is inclined relative to the probing direction at an angle.

7. The microelectromechanical probe as claimed in claim 6, wherein the angle is larger than or equal to 45 degrees and smaller than or equal to 75 degrees.

8. A probe set comprising at least two microelectromechanical probes as claimed in claim 1, the pinpoint portion of each of the microelectromechanical probes having a rear side substantially opposite to the cutting face, the rear sides of the pinpoint portions of two said microelectromechanical probes facing each other.

9. A method of manufacturing a microelectromechanical probe comprising the steps of:
a) forming a probe body on a substrate by a microelectromechanical system manufacturing process in a way that the probe body has a bottom surface facing the substrate, a top surface opposite to the bottom surface, a body portion, and a pinpoint portion which is substantially extended in a probing direction from the body portion and provided with a first side, a second side opposite to the first side and a probing end substantially oriented in the probing direction; and
b) cutting the pinpoint portion of the probe body from the first side to the second side in a cutting direction non-parallel to the probing direction by a cutting tool, so as to simultaneously provide the pinpoint portion a cutting face on the top surface and reduce an area of the probing end in a way that the cutting face is provided at an edge thereof with an edge cut mark and the cutting face descends from the edge cut mark to the probing end.

10. The method as claimed in claim 9, wherein in the step a), a sacrificial layer is formed on the substrate, and the probe body is fixed on the substrate by the sacrificial layer; the sacrificial layer is removed after the step b), so that the probe body is separated from the substrate.

11. The method as claimed in claim 9, wherein in the step a), a plurality of said probe bodies are formed on the substrate in a way that the probe bodies are substantially arranged at a same posture and the probing ends of the probe bodies are aligned in the cutting direction; in the step b), the plurality of said probe bodies, which are aligned in an imaginary straight line in the cutting direction, are cut by the cutting tool in a same cutting process.

12. The method as claimed in claim 9, wherein the cutting tool is one of a ball nose milling cutter, an abrasive wheel, a form grinding wheel, a single-tooth milling cutter and a multi-tooth milling cutter.

13. The method as claimed in claim 9, wherein the cutting direction is substantially perpendicular to the probing direction.

14. The method as claimed in claim 9, wherein the cutting direction is inclined relative to the probing direction at an angle.

15. The method as claimed in claim 14, wherein the angle is larger than or equal to 45 degrees and smaller than or equal to 75 degrees.

16. The method as claimed in claim 9, wherein the cutting face is substantially shaped as one of a plane, a curved surface and a combination of multiple curved surfaces.

17. The method as claimed in claim 9, wherein the cutting face is defined with a minimum length, which is a minimum distance measured in a direction parallel to the probing direction between the edge cut mark and the probing end, and a descending height, which is a minimum distance measured in a direction perpendicular to the probing direction between the edge cut mark and the probing end; the minimum length is larger than or equal to 1.5 times of the descending height.

18. The method as claimed in claim 9, wherein the cutting face is substantially shaped as a plane inclined relative to the probing direction at an angle smaller than 33 degrees.
